(19) United States
(12) Patent Application Publication
(10) Pub. No.: US 2019/0371995 A1
(43) Pub. Date: Dec. 5, 2019

(54) THERMOELECTRIC DEVICE WITH PARALLEL ELEMENTS

(71) Applicant: Faurecia Automotive Seating, LLC, Auburn Hills, MI (US)

(72) Inventor: Shaun Dorian Tait, Troy, MI (US)

(21) Appl. No.: 15/991,130

(22) Filed: May 29, 2018

(51) Int. Cl. H01L 35/32; B60N 2/56

(52) U.S. Cl. CPC H01L 35/32; B60N 2/5685; B60N 2/5642

(57) ABSTRACT

A thermoelectric device includes a plurality of thermoelectric elements arranged in parallel between electrically conductive layers, along with a voltage reducer arranged in series with at least one pair of N- and P-thermoelements to facilitate the parallel arrangement. The device can be made in sheet form with flexible conductive layers to form a pliable layer for use beneath the trim cover of a vehicle seat.

### TECHNICAL FIELD

The present disclosure relates to thermoelectric devices and, in particular, to thermoelectric devices for use in vehicles and vehicle seats.

### BACKGROUND

Thermoelectric devices are solid-state electrically powered heat pumps that rely on the Peltier effect to provide a temperature difference along their opposite sides. The Peltier effect is exhibited when a DC voltage is applied and current flows across a junction of two dissimilar materials. The temperature of the junction will either increase or decrease in temperature, depending on the polarity of the applied voltage and the resulting direction of current flow. Conventional thermoelectric devices are relatively small electronic devices in which the dissimilar materials include an n-type semiconductor paired with a p-type semiconductor with the junction formed between them. Thermoelectric devices typically include multiple pairs of such materials arranged electrically in series to provide a corresponding multiple number of junctions. This effectively scales up the energy transfer capacity of the device, which is proportional to the number of junctions. It also makes the device practical for use with commonly available DC voltages, such as a 12-volt automotive electrical system.

In WO 2007/109368, Lindstrom et al. teach a thermoelectric device with electric current carrying substrates that allow higher current carrying capacity between individual thermoelements of the device via the use of electrical conductors on both the interior and the exterior sides of the substrates. The thermoelements are electrically connected in series between the substrates, and the exterior conductors perform an additional function as strengthening elements.

### SUMMARY

In accordance with one or more embodiments, a thermoelectric device includes a first electrically conductive layer, a second electrically conductive layer, a plurality of thermoelectric elements, and a voltage reducer. The first electrically conductive layer is adapted for connection with one pole of a power source, and the second electrically conductive layer is adapted for connection with an opposite pole of the power source. The thermoelectric elements are arranged electrically in parallel with one another between the first and second conductive layers. Each thermoelectric element including a thermoelement pair comprising a p-type thermoelement and an n-type thermoelement arranged electrically in series with each other across the first and second conductive layers. The voltage reducer is arranged in electrical series with at least one of the thermoelement pairs such that, when the thermoelectric device is connected to the power source, a voltage drop across each thermoelement pair is less than a voltage across the poles of the power source.

In some embodiments, the voltage reducer is a resistor arranged in electrical series with one of the thermoelement pairs between the first and second conductive layers.

In some embodiments, the thermoelectric device includes a plurality of resistors, and each of the thermoelectric elements includes one of the resistors arranged in electrical series with one of the thermoelement pairs between the first and second conductive layers.

In some embodiments, the voltage reducer is a resistor in-line with a power lead adapted to connect one of the conductive layers to the power source.

In some embodiments, the voltage reducer is a voltage regulator.

In some embodiments, the voltage reducer is a low voltage power supply powered by the power source.

In some embodiments, the first and second conductive layers are flexible layers and the plurality of thermoelectric elements is arranged as a layer between the first and second conductive layers such that the thermoelectric elements are permitted to move out of plane with respect to one another.

In some embodiments, the thermoelectric device includes an electrically insulating layer located between the first and second conductive layers and extending between adjacent thermoelectric elements of the plurality.

In some embodiments, the thermoelectric device includes first and second protective layers, and the first and second conductive layers and the plurality of thermoelectric elements are located between the protective layers.

In some embodiments, the thermoelectric device includes a heat sink coupled with one of the conductive layers.

In some embodiments, the plurality of thermoelectric elements is arranged between the first and second conductive layers in a U-shaped or X-shaped pattern.

In some embodiments, the thermoelectric device is disposed between a foam layer and a trim cover of a vehicle seat. The foam layer may be a reticulated foam layer, and the seat may include an air mover arranged to provide air flow through the reticulated foam. The foam layer may include an air flow channel formed therein and the seat may include an air mover arranged to provide air flow through the air channel.

In some embodiments, the voltage reducer comprises an air mover configured to cause air to flow along the foam layer to extract heat from the thermoelectric device.

Various aspects, embodiments, examples, features and alternatives set forth in the preceding paragraphs, in the claims, and/or in the following description and drawings may be taken independently or in any combination thereof. For example, features disclosed in connection with one embodiment are applicable to all embodiments in the absence of incompatibility of features.

### BRIEF DESCRIPTION OF THE DRAWINGS

Exemplary embodiments will hereinafter be described in conjunction with the appended drawings, wherein like designations denote like elements, and wherein:

FIG. 1 is a cross-sectional side view of an illustrative thermoelectric device as part of a seat bottom;

FIG. 2 is an enlarged view of a portion of FIG. 1, illustrating a plurality of thermoelectric elements arranged in parallel with each other between conductive layers;

FIG. 3 is an enlarged view of another example of the thermoelectric device where the voltage reducer is located in-line with a power lead of the device;

FIG. 4 is a top view of a seat bottom illustrating an arrangement of the plurality of thermoelectric elements in a square array;

FIG. 5 is a top view of a seat bottom illustrating an arrangement of the plurality of thermoelectric elements in a U-shaped pattern;

FIG. 6 is a top view of a seat bottom illustrating an arrangement of the plurality of thermoelectric elements in an X-shaped pattern;

FIG. 7 depicts a thermal energy distribution along the thermoelectric device of FIG. 6; and

FIG. 8 depicts a thermal energy distribution extending away from a centrally located conventional thermoelectric device.

### DETAILED DESCRIPTION

The thermoelectric device described below is configured with a plurality of thermoelectric elements arranged in parallel between electrically conductive layers. A voltage reducer is arranged in series with at least one pair of thermoelements to facilitate the parallel arrangement. The device can be made in sheet form with flexible conductive layers to form a pliable thermoelectric device for use beneath the trim cover of a vehicle seat. The parallel arrangement eliminates the need to serially connect large numbers of thermoelectric elements, offering design freedom and preventing total device failure when a single thermoelectric element fails.

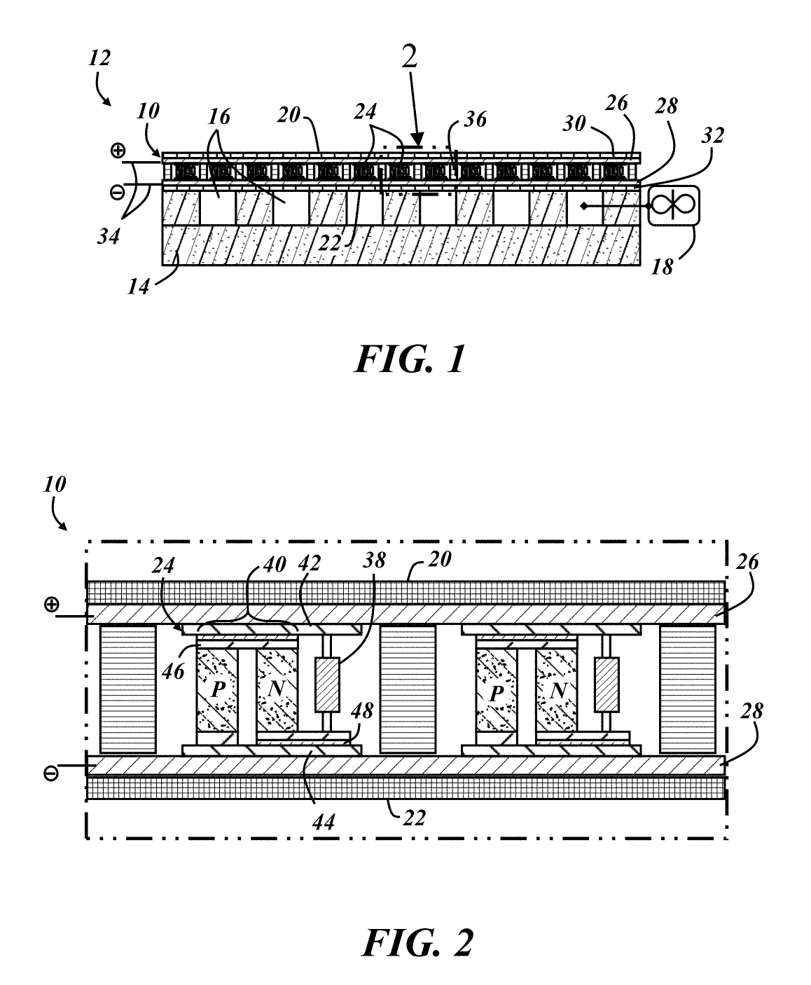

FIG. 1 is a cross-sectional side view of a thermoelectric device (TED) 10 as part of a vehicle seat component 12, such as a seat bottom or a seat back. The seat component 12 includes the thermoelectric device 10 overlying a foam layer 14 with air channels 16 formed therein. A trim cover (not shown) at least partly defines a seating surface of the seat and overlies the thermoelectric device 10. An air mover 18 is schematically illustrated as having an inlet or outlet in fluid connection with the air channels 16 and is configured to provide air flow through and along the air channels. The air mover 18 may be a fan, a blower, or other device capable of inducing air flow through the air channels 16. The seat component 12 may include other elements, such as structural frame members, additional air channels and/or foam layers, sensors, adjustment devices, etc. It should also be understood that the figures are not to scale, with components of the thermoelectric device 10 exaggerated in size for purposes of illustration, for example.

In operation in a cooling mode, power is applied to the thermoelectric device 10 from a power source with a polarity such that a first side 20 is the “cold” side and an opposite second side 22 is the “hot” side. The air mover 18 operates to pull heat away from the second side 22 of the device 10 via forced convection to help maintain a thermal gradient across its opposite sides 20, 22. The heated air can be discharged at a location away from the seating surface, such as beneath the seat or outside the vehicle. A heat sink or heat sink layer made from a thermally conductive (e.g., metallic) material with increased surface area for the air to flow along may be included at the second side 22 of the thermoelectric device 10 to enhance heat exchange between the TED and the flowing air. Alternatively, the foam layer 14 is a layer of reticulated foam or a 3D-mesh material that underlies the TED 10, with the air mover 18 operating to provide air flow through the layer to exchange thermal energy with the second side 22 of the TED. The polarity of the applied voltage can be reversed to place the TED 10 in a heating mode.

The illustrated thermoelectric device 10 includes a plurality of individual thermoelectric elements 24 spaced apart from each other and arranged between first and second conductive layers 26, 28, which are interposed between first and second protective layers 30, 32 in this example. Each of the conductive layers 26, 28 is adapted for connection with a power source via power leads 34. The illustrated TED 10 also includes an electrically insulating layer 36 between the conductive layers 26, 28 with portions extending between adjacent thermoelectric elements 24. While at first glance, the TED 10 of FIG. 1 looks similar to a conventional TED, with a plurality of individual thermoelectric elements 24 between conductive layers which are between additional outer layers, it is fundamentally different. In particular, the multiple thermoelectric elements of a conventional TED are electrically connected together in series across opposite electrodes, while the thermoelectric elements 24 of the disclosed TED 10 are arranged electrically in parallel with one another between the first and second conductive layers 26, 28.

This electrically parallel arrangement of thermoelectric elements 24 is made possible by a voltage reducer 38 (not shown in FIG. 1) arranged in electrical series with a thermoelement pair of at least one of the thermoelectric elements 24, as discussed further below. The parallel arrangement also offers design flexibility since a wire or other conductor does not have to extend separately between every single one of the thermoelements, of which there may be hundreds. For example, while the conductive layers of conventional TEDs are typically copper traces deposited and/or etched onto ceramic outer layers in a complex pattern designed with hundreds of discrete segments, the conductive layers 26, 28 of the disclosed TED 10 can each be made as a continuous conductive sheet with one layer 26 interconnecting one side of all of the plurality of thermoelectric elements 24, and the other layer 28 interconnecting the other side of all of the plurality of thermoelectric elements. This design freedom allows the TED 10 to be made in flexible sheet form, as is also discussed further below, and removes upper and lower limitations on the number of thermoelectric elements that can be included in a single TED.

FIG. 2 is an enlarged view of a portion of the thermoelectric device 10 of FIG. 1 illustrating one example of a voltage reducer 38, which in this case is a resistor. In this example, each one of the plurality of thermoelectric elements 24 that are placed in parallel across the first and second conductive layers 26, 28 includes a resistor 38 arranged in electrical series with a thermoelement pair 40 of each thermoelectric element 24. Each thermoelement pair 40 includes a first thermoelement (P) made from a p-type semiconductor and a second thermoelement (N) made from an n-type semiconductor. The resistor 38 of each element 24 is sized to limit the amount of current allowed to flow through the respective thermoelement pair 40 for a given voltage potential across the conductive layers 26, 28. Stated differently, the voltage drop across each thermoelement pair 40 is less than the voltage of the power source of the TED 10. For example, when the TED 10 is connected to a 12-volt DC power source, the serial resistor 38 can limit the voltage drop across the thermoelement pair 40 to a level in the tens of millivolts range.

In the exemplary embodiment of FIG. 2, each thermoelectric element 24 includes first and second electrodes 42, 44 in respective contact with the first and second conductive layers 26, 28. One end of the resistor 38 is connected to the first electrode 42, and the other end of the resistor is connected to an end of the N-element via an electrical lead. The other end of the N-element is connected to one end of the P-element via another electrical lead, which represents a thermoelectric junction 46 for the pair 40. Both of these electrical leads are electrically insulated from the electrodes 42, 44 by insulating layers 48. The other end of the P-element is connected to the second electrode 44 by another electrical lead to complete the series arrangement of the resistor 38 and thermoelement pair 40. The direction of electric current flow across the thermoelectric junction 46 determines which is the “hot” side and which is the “cold” side of the thermoelectric element 24. In the illustrated example, current flows across the junction 46 from the N-element to the P-element which tends to cause heat to flow in a direction from the first side 20 toward the second side 22 of the TED, making the illustrated thermoelectric junction 46 the “cold” side of the thermoelement pair 40.

Other resistive arrangements are possible. For instance, each thermoelectric element 24 may include multiple thermoelement pairs 40 in series with the resistor 38, such as two, three, four, or up to ten thermoelement pairs, with the resistor sized accordingly and a decreasing resistor size required with an increasing number of thermoelement pairs 40. In other non-limiting examples, the resistor 38 could be relocated to interconnect the first conductive layer 26 of the TED with the first electrode 42 of the thermoelectric element 24, the resistor could be located on the other side of the thermoelement pair 40, or multiple resistors could be used in various parts of each thermoelectric element in series with the thermoelement pair 40. In some embodiments, a body of the resistor 38 is placed in physical contact with the second conductive layer 28 or the second electrode 44, which can take advantage of any heat sink and/or forced air flow in an adjacent layer to pull heat away from the resistor.

The size of the resistor 38 is a function of the applied voltage, the effective resistance of the thermoelement pair(s) 40, and the current carrying capacity of each thermoelement pair. In its simplest terms,

$$R = \frac{V}{{I}_{max}} - {R}_{TE} , \qquad ( 1 )$$

where R is the resistance of the resistor 38, V is the voltage of the power source, Iₘₐₓ is the maximum allowable current for the thermoelement pair 40, and R_{TE} is the effective resistance of the thermoelement pair. Where more than one resistor is placed in series with the thermoelement pair, R=R₁+R₂, with R₁ and R₂ being respective resistance values for each resistor. Where the thermoelectric element includes more than one thermoelement pair 40, R_{TE}=nRₜₑ, where Rₜₑ is the resistance of a single thermoelement pair, and n is the number of thermoelement pairs placed in series with the resistor(s).

Other factors or system variables may need to be considered, such as the impedance of the power source, the resistance of the electrodes, electrical leads, power leads, and other electrical connections within the thermoelectric element, temperature dependence of the variables, etc. Iₘₐₓ may be a current rating for the thermoelement pair rather than a maximum failure current. Skilled artisans will be able to select a suitable resistance value for the resistor 38 without undue experimentation with the understanding that the resistor functions to limit current through the thermoelement pair 40.

In one non-limiting example in a vehicle application in which the vehicle operates on a 12-volt DC electrical system, a single thermoelement pair with a rated current capacity Iₘₐₓ of 4 amperes and an effective resistance R_{TE} of 15 milliohms is placed in series with a resistor have a resistance R of 2.985 ohms. Without the resistor 38, application of 12 volts across the low resistance thermoelement pair could result in several hundred amps of current, which would blow a fuse in the vehicle electrical system and/or burn the thermoelement pair like a fuse. This is partly why a conventional thermoelectric device for use with a 12-VDC vehicle system typically includes approximately 200 thermoelement pairs arranged in series with each other. These numbers are of course used only as a non-limiting example and are presented here with easily divisible numbers for purposes of simplicity in explanation. Skilled artisans will appreciate, for example, that a 12-VDC vehicle electrical system usually operates in a range of voltages closer to 15 volts. Additionally, certain resistance values may require the use of more than one resistor in series with the thermoelement pair.

The resistors and other voltage reducers 38 discussed below allow the thermoelectric elements 24 to be placed in parallel electrical arrangements with other thermoelectric elements without upper or lower limits on the number of thermoelement pairs in the device. Conventional thermoelectric devices are limited to a minimum number of thermoelement pairs required to limit the total current through the device to a level each individual thermoelement pair can accommodate, and they are limited to a maximum number of thermoelement pairs above which the current is insufficiently low for the thermoelement pair to exhibit the thermoelectric effect. Further, the parallel arrangement can continue to function if or when one of the thermoelectric elements fails, unlike conventional thermoelectric devices in which the failure of one thermoelement pair means failure of the entire device.

While the resistors 38 are illustrated as traditional axial-lead resistors with a fixed resistance, other types of resistors may be used, such as radial-lead or surface mount (SMT) resistors. It is also possible to employ a resistor with variable resistance that, for example, changes resistance with changing voltage of the power supply to ensure proper current limitation during high voltage peaks.

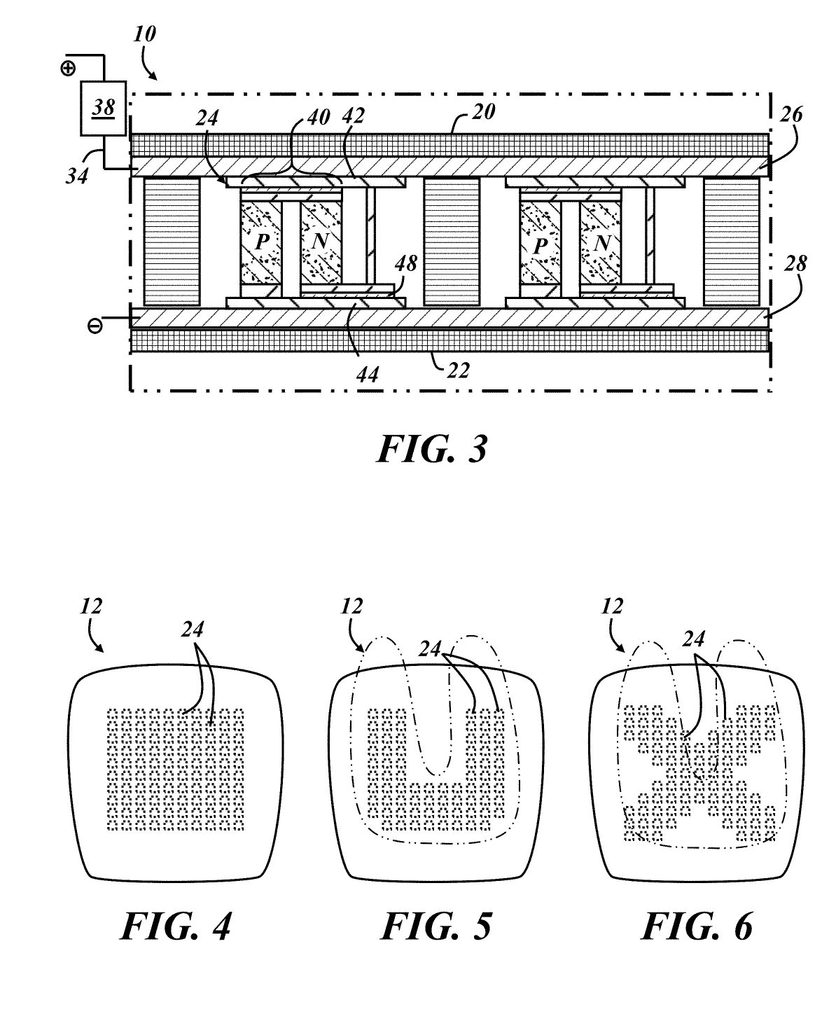

In the example of FIG. 3, the voltage reducer 38 is in-line with one of the power leads 34 of the TED 10. In this configuration, the voltage reducers are omitted from each individual thermoelectric element 24 and replaced with another electrical lead to connect the first electrode 42 of the thermoelectric element 24 with the end of the N-element that is not connected to the P-element. This embodiment uses less overall electronic components and allows the voltage reducer 38 to be located elsewhere in the vehicle seat or elsewhere in the vehicle. For example, the voltage reducer could be located in the air channels 16 formed in the foam layer 14 of FIG. 1 to benefit from any additional cooling capacity of the air flowing therethrough.

In one embodiment, the voltage reducer 38 is a resistor that is in-line with one of the power leads 34. In this manner a single resistor can be placed in series with all of the thermoelectric elements 24 of the TED. The principle of operation is the same as in the previous example, with the resistor 38 being sized to limit the current through the thermoelement pairs 40 to a tolerable level. adapted to connect one of the conductive layers to the power source. The resistance for the in-line resistor can be generally determined using the relationship in equation (1) above, with R_{TE} being the total resistance of all of the parallel thermoelectric elements 24 across the two conductive layers 26, 28, or the inverse of the sum of the inverses of the resistances of each thermoelectric element in parallel.

In another embodiment, the voltage reducer 38 is a voltage regulator, such as a linear regulator or a switching regulator, which in some cases can be part of an integrated circuit along the power lead or otherwise in series with the parallel-arranged thermoelectric elements. This type of voltage reducer 38 has the added advantage of maintaining a constant voltage across the first and second conductive layers 26, 28, even in a vehicle electrical system in which the voltage varies based on temperature, engine speed, etc. The voltage reducer could also be in the form of a low voltage power supply powered by the power source that brings the power source voltage down to a level that limits the current through the thermoelectric elements to a tolerable level.

In another embodiment, the voltage reducer includes or is the above-described air mover 18 which is configured to help remove waste heat from the second side 22 of the TED 10. In this configuration, at least some of the energy used or dissipated by the voltage reducer 38 goes to improving system efficiency. Other types of electric devices that provide other vehicle or vehicle seat functions could be placed in-line with the parallel-arranged thermoelectric elements to drop the voltage across the conductive layers 26, 28 to a sufficiently low level. The voltage reduce may include more than one resistor, regulator, or electric device.

As noted above, the parallel arrangement of the thermoelectric elements 24 provides additional design freedom, including the ability to make the TED 10 in the form of a flexible sheet, similar to a heating pad. Conventional TEDs sandwich the thermoelements between rigid ceramic plates, making them difficult to use in vehicle seating applications without the seat occupant experiencing some discomfort. In the illustrated thermoelectric device, the first and second conductive layers 26, 28 may be flexible layers such that the thermoelectric elements 24 are permitted to move out of plane with respect to one another, such as when a person sits on a seat with the TED 10 installed. The conductive layers 26, 28 may also be continuous within their perimeters. Examples of suitable conductive layers include, for example, a metallic (e.g., copper, silver, aluminum, etc.) weave or mesh, graphene, or textile materials woven from conductive materials or partly woven with metallic or other conductive thread. Preferably the conductive layers 26, 28 are both electrically conductive and thermally conductive. As used herein, “flexible” means the layer can bent and/or deformed without damaging the layer so that the layer can generally conform to the shape of an adjacent layer under load.

The protective layers 30, 32 may be provided to isolate the conductive layers 26, 28 and the thermoelectric elements 24 from the environment and/or to encase those components into a device that can be handled in a manufacturing environment. Useful properties of the protective layers 30, 32 include electrical insulation, flexibility, and water resistance, for example. Thin polymer films or synthetic fabrics are examples of suitable protective layers 30, 32. In embodiments including one or more heat sinks at the second side 22 of the TED, the heat sink can be attached directly to the second conductive layer 28 and extend through the protective layer. Unlike with conventional TEDs, the heat sink does not have to be isolated from the conductive layers since there is no chance of inadvertently shorting across separate thermoelectric elements.

The electrically insulating layer 36 is located between the first and second conductive layers 26, 28 and extends between adjacent thermoelectric elements 24. The insulating layer 36 solves a problem that was previously unknown in the art of thermoelectric devices and only discovered as a problem when the disclosed parallel arrangement of thermoelectric elements 24 enabled the use of flexible layers rather than rigid layers on opposite sides of the thermoelement pairs 40. In particular, the relative movement permitted among the various layers and among the thermoelectric elements 24 opens the possibility of the conductive layers 26, 28 touching each other, effectively shorting the electrodes of the device. Such flexibility also could permit adjacent thermoelectric elements 24 between the layers to touch each other, depending on their relative spacing and the degree of deformation of the flexible TED. The electrically insulating layer 36 prevents this unwanted contact among TED components. The layer 36 can be made from a sheet of electrically insulating material with cut-outs or apertures cut through the sheet to accommodate each one of the thermoelectric elements 24 passing through it. The insulating layer 36 may be made from a flexible and compressible material, such as a foam material.

With no limits on the number of thermoelement pairs, the areal size of the TED is not limited. Conventional TEDs are typically small electronic components, such as 30-50 mm in the non-thickness directions. As illustrated in the examples of FIGS. 4-6, the above-described sheet-form TED can be scaled-up to the size of the seat bottom 12 of a vehicle seat, for example. FIG. 4 illustrates a top view of the seat bottom 12 with the shape of the array of thermoelectric elements 24 shown. The array of FIG. 4 is in a square shape. In the example of FIG. 5, the plurality of thermoelectric elements 24 is arranged between the first and second conductive layers in a U-shaped pattern, and in the example of FIG. 6, the plurality of thermoelectric elements 24 is arranged between the first and second conductive layers in an X-shaped pattern. The general area of the upper leg and pelvic region of a seat occupant is superimposed over the seat bottoms 12 of FIGS. 5 and 6. The thermoelectric device can thus be tailored to place the individual thermoelectric elements where they are most useful—i.e., where the seat occupant's body contacts the seat.

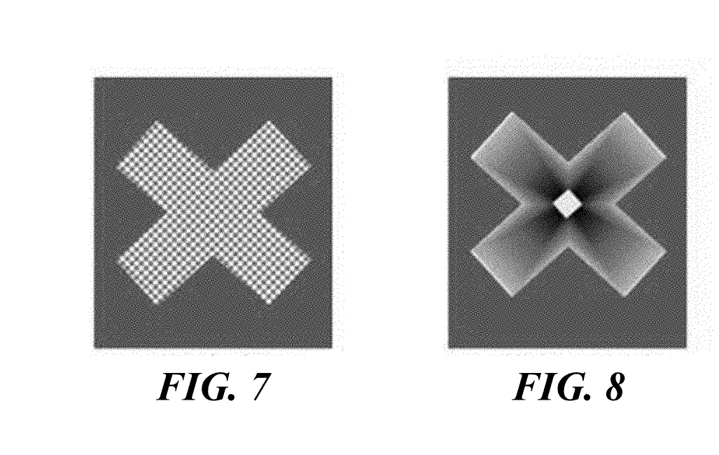

FIGS. 7 and 8 illustrate simulated thermal energy distributions along the seating surface of a seat bottom, with the above described TED having electrically parallel thermoelectric elements arranged in an X-shaped pattern in FIG. 7, and with a conventional configuration in FIG. 8. In the example of FIG. 7 according to the present disclosure, thermal energy is distributed evenly among the plurality of individual thermoelectric elements distributed as a layer between conductive layers and arranged in parallel. In the example of FIG. 8, a relatively small TED (e.g., 30-50 mm square) is centered along the seat bottom, and the thermal energy distribution includes temperature gradients in the directions away from the central TED. This is the case even when graphene conductive layers are attached to the central TED and disposed beneath the seating surface. The above-described thermoelectric device thus offers the further advantage of a more even thermal energy distribution.

The increased design flexibility also allows different thermal energy densities or thermal gradients to be intentionally provided by the TED 10. For example, while the examples of FIGS. 4-6 illustrate the plurality of thermoelectric elements of each TED 10 equally spaced from one another. In other embodiments, the thermoelectric elements 24 are spaced from each other by different amounts—i.e., closer together in areas where high thermal energy transfer is desired, and farther apart in areas where lower thermal energy transfer is desired.

Placing a voltage reducer in series with a plurality of thermoelement pairs that are arranged in parallel with each other may be considered a method of limiting the electrical current through the thermoelement pairs. The method may include providing a power source having a voltage and providing a plurality of thermoelement pairs arranged in parallel with each other and each having an electrical resistance and an electric current threshold, wherein an electric current resulting from applying the voltage across the thermoelement pair is greater than the electric current threshold. The method may further include limiting the current flow through the thermoelectric pairs by placing a voltage reducer, such as a resistor, regulator, or functional device in series with the thermoelectric pairs before completing the circuit.

It is to be understood that the foregoing is a description of one or more preferred exemplary embodiments of the invention. The invention is not limited to the particular embodiment(s) disclosed herein, but rather is defined solely by the claims below. Furthermore, the statements contained in the foregoing description relate to particular embodiments and are not to be construed as limitations on the scope of the invention or on the definition of terms used in the claims, except where a term or phrase is expressly defined above. Various other embodiments and various changes and modifications to the disclosed embodiment(s) will become apparent to those skilled in the art. All such other embodiments, changes, and modifications are intended to come within the scope of the appended claims.

As used in this specification and claims, the terms “for example,” “for instance,” “such as,” and “like,” and the verbs “comprising,” “having,” “including,” and their other verb forms, when used in conjunction with a listing of one or more components or other items, are each to be construed as open-ended, meaning that that the listing is not to be considered as excluding other, additional components or items. Other terms are to be construed using their broadest reasonable meaning unless they are used in a context that requires a different interpretation.

1. A thermoelectric device, comprising:
a first electrically conductive layer adapted for connection with one pole of a power source;
a second electrically conductive layer adapted for connection with an opposite pole of the power source;
a plurality of thermoelectric elements arranged electrically in parallel with one another between the first and second conductive layers, each thermoelectric element including a thermoelement pair comprising a p-type thermoelement and an n-type thermoelement arranged electrically in series with each other across the first and second conductive layers; and
a voltage reducer arranged in electrical series with at least one of the thermoelement pairs such that, when the thermoelectric device is connected to the power source, a voltage drop across each thermoelement pair is less than a voltage across the poles of the power source.

2. A thermoelectric device as defined in claim 1, wherein the voltage reducer is a resistor arranged in electrical series with one of the thermoelement pairs between the first and second conductive layers.

3. A thermoelectric device as defined in claim 2, further comprising a plurality of resistors, wherein each of the thermoelectric elements includes one of the resistors arranged in electrical series with one of the thermoelement pairs between the first and second conductive layers.

4. A thermoelectric device as defined in claim 2, wherein the resistor is in-line with a power lead adapted to connect one of the conductive layers to the power source.

5. A thermoelectric device as defined in claim 1, wherein the voltage reducer is a voltage regulator.

6. A thermoelectric device as defined in claim 1, wherein the voltage reducer is a low voltage power supply powered by the power source.

7. A thermoelectric device as defined in claim 1, wherein the first and second conductive layers are flexible layers and the plurality of thermoelectric elements is arranged as a layer between the first and second conductive layers such that the thermoelectric elements are permitted to move out of plane with respect to one another.

8. A thermoelectric device as defined in claim 1, further comprising an electrically insulating layer located between the first and second conductive layers and extending between adjacent thermoelectric elements of the plurality.

9. A thermoelectric device as defined in claim 1, further comprising first and second protective layers, wherein the first and second conductive layers and the plurality of thermoelectric elements are located between the protective layers.

10. A thermoelectric device as defined in claim 1, further comprising a heat sink coupled with one of the conductive layers.

11. A thermoelectric device as defined in claim 1, wherein the plurality of thermoelectric elements is arranged between the first and second conductive layers in a U-shaped or X-shaped pattern.

12. A vehicle seat comprising a thermoelectric device as defined in claim 1, wherein the thermoelectric device is disposed between a foam layer and a trim cover of the seat.

13. A vehicle seat as defined in claim 12, wherein the foam layer is a reticulated foam layer and the seat further comprises an air mover arranged to provide air flow through the reticulated foam.

14. A vehicle seat as defined in claim 12, wherein the foam layer includes an air flow channel formed therein and the seat further comprises an air mover arranged to provide air flow through the air channel.

15. A vehicle seat as defined in claim 12, wherein the voltage reducer comprises an air mover configured to cause air to flow along the foam layer to extract heat from the thermoelectric device.
